(19) United States
(12) Patent Application Publication
(10) Pub. No.: US 2020/0251691 A1
(43) Pub. Date: Aug. 6, 2020

(54) APPARATUS FOR VACUUM PROCESSING OF A SUBSTRATE, SYSTEM FOR VACUUM PROCESSING OF A SUBSTRATE, AND METHOD FOR TRANSPORTATION OF A SUBSTRATE CARRIER AND A MASK CARRIER IN A VACUUM CHAMBER

(71) Applicant: Applied Materials, Inc., Santa Clara, CA (US)

(72) Inventor: Matthias HEYMANNS, Münster (DE)

(21) Appl. No.: 15/761,064

(22) PCT Filed: Apr. 12, 2017
(86) PCT No.: PCT/EP2017/058828

§ 371 Date: Mar. 16, 2018

(30) Foreign Application Priority Data
Mar. 17, 2017 (EP) PCT/EP2017/056383

(51) Int. Cl. H01L 51/56; C23C 14/04

(52) U.S. Cl. CPC H01L 51/56; C23C 14/042

(57) ABSTRACT

An apparatus for vacuum processing of a substrate is described. The apparatus includes a vacuum chamber, a substrate transport assembly, a mask transport assembly, and an alignment system having an actuator and a mechanical isolation element between the actuator and the vacuum chamber.

### FIELD

Embodiments of the present disclosure relate to an apparatus for vacuum processing of a substrate, a system for vacuum processing of a substrate, and a method for transportation of a substrate carrier and a mask carrier in a vacuum chamber. Embodiments of the present disclosure particularly relate to carriers for holding substrates and masks used in the manufacture of organic light-emitting diode (OLED) devices.

### BACKGROUND

Techniques for layer deposition on a substrate include, for example, thermal evaporation, physical vapor deposition (PVD), and chemical vapor deposition (CVD). Coated substrates may be used in several applications and in several technical fields. For instance, coated substrates may be used in the field of organic light emitting diode (OLED) devices. OLEDs can be used in the manufacture of television screens, computer monitors, mobile phones, other hand-held devices, and the like for displaying information. An OLED device, such as an OLED display, may include one or more layers of an organic material situated between two electrodes that are all deposited on a substrate.

The functionality of an OLED device can depend on a coating thickness of the organic material. The thickness has to be within a predetermined range. In the production of OLED devices, there are technical challenges with respect to the deposition of evaporated materials in order to achieve high resolution OLED devices. In particular, accurate and smooth transportation of substrate carriers and mask carriers through a processing system remains challenging. Further, a precise alignment of the substrate with respect to the mask is crucial for achieving high quality processing results, e.g. for production of high resolution OLED devices.

In view of the above, new carriers for vacuum processing of a substrate, systems for vacuum processing of a substrate, and methods for transportation of a substrate carrier and a mask carrier in a vacuum chamber that overcome at least some of the problems in the art are beneficial. The present disclosure particularly aims at providing carriers that can be efficiently transported in a vacuum chamber.

### SUMMARY

In light of the above, an apparatus for vacuum processing of a substrate, a system for vacuum processing of a substrate, and a method for transportation of a substrate carrier and a mask carrier in a vacuum chamber are provided. Further aspects, benefits, and features of the present disclosure are apparent from the claims, the description, and the accompanying drawings.

According to an aspect of the present disclosure, an apparatus for vacuum processing of a substrate is provided. The apparatus includes a vacuum chamber, a substrate transport assembly, a mask transport assembly, and an alignment system having an actuator and a mechanical isolation element between the actuator and the vacuum chamber.

According to an aspect of the present disclosure, an apparatus for vacuum processing of a substrate is provided. The apparatus includes a vacuum chamber, a substrate track assembly, a mask track assembly, and an alignment system having an actuator and a mechanical isolation element between the actuator and the vacuum chamber.

According to another aspect of the present disclosure, a system for vacuum processing of a substrate is provided. The system includes the apparatus for vacuum processing of a substrate according to the embodiments described herein, the substrate carrier and the mask carrier.

According to a further aspect of the present disclosure, a method for transportation of a substrate carrier and a mask carrier in a vacuum chamber is provided. The method includes aligning the substrate carrier and the mask carrier relative to each other with an actuator of an alignment system in the vacuum chamber, compensating or reducing at least one of mechanical noise, dynamic deformations and static deformations transferred from the vacuum chamber to the actuator.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic view of a first track assembly or first transport assembly and a substrate carrier according to embodiments described herein;

FIG. 1B shows a schematic view of a second track assembly or second transport assembly and a mask carrier according to embodiments described herein;

FIG. 2 shows a schematic view of an apparatus for vacuum processing of a substrate according to embodiments described herein;

FIG. 3A shows a schematic view of an apparatus for vacuum processing of a substrate having an alignment system or holding arrangement according to embodiments described herein;

FIG. 3B shows a schematic view of an apparatus for vacuum processing of a substrate having an alignment system or a holding arrangement according to embodiments described herein;

FIGS. 4 and 5 show schematic views of an apparatus for vacuum processing of a substrate having an alignment system or a holding arrangement according to further embodiments described herein;

FIG. 6 shows a schematic view of an apparatus for vacuum processing of a substrate having an alignment system or an alignment system or a holding arrangement according to further embodiments described herein;

FIG. 7 shows a schematic view of a system for vacuum processing of a substrate according to embodiments described herein;

FIG. 8 shows a flow chart of a method for transportation of a substrate carrier and a mask carrier in a vacuum chamber according to embodiments described herein;

FIG. 9A shows a schematic view of a portion of an apparatus for vacuum processing of a substrate having an alignment system or an alignment system or a holding arrangement according to further embodiments described herein; and

FIG. 9B shows an alignment frame utilize e.g. in the apparatus of

FIG. 9A according to some embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The present disclosure provides a first track assembly or first transport assembly for a substrate carrier and a second track assembly or second transport assembly for a mask carrier that may be equally sized in at least one dimension. In other words, the mask carrier may fit into the first track arrangement and the substrate carrier may fit into the second track arrangement. The first track arrangement and the second track arrangement can be flexibly used while providing an accurate and smooth transportation of the carriers through the vacuum system. A track assembly refers to a track for transportation of carriers and may, thus, be referred to as transport assembly. An alignment system or holding arrangement allows for a precise alignment of the substrate with respect to the mask, or vice versa. A high quality processing results, e.g. for production of high resolution OLED devices, can be achieved.

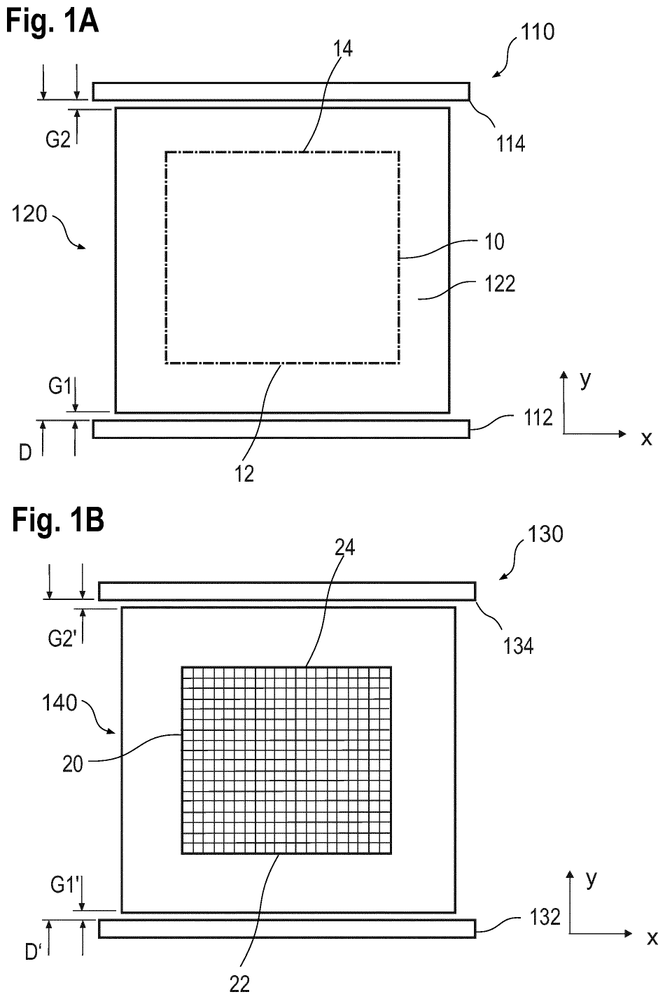

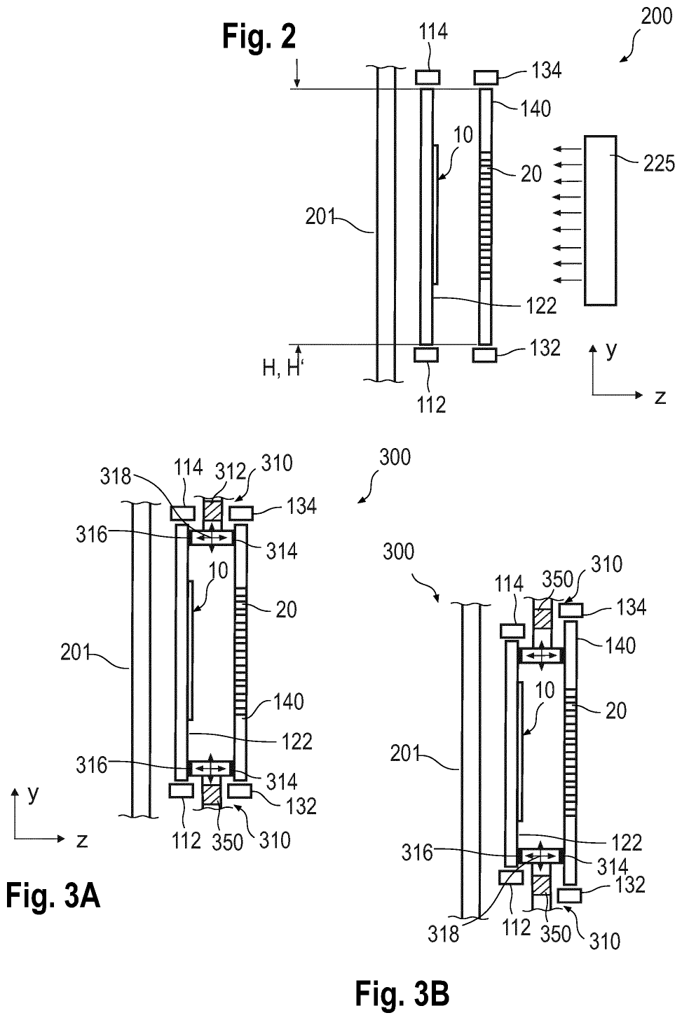

FIG. 1A shows a schematic view of a first transport assemblyl10 and a substrate carrier 120. FIG. 1B shows a schematic view of a second transport assemb1y130 and a mask carrier 140. FIG. 2 shows a schematic view of an apparatus 200 for vacuum processing of a substrate 10 according to embodiments described herein.

The apparatus 200 includes a vacuum chamber, the first transport assemblyl10 configured for transportation of the substrate carrier 120, the second transport assemblyl30 configured for transportation of the mask carrier 140, and an alignment system configured for positioning the substrate carrier 120 and the mask carrier 140 with respect to each other. The first transport assemblyl10 includes a first portion, such as a first track 112, configured to support the substrate carrier 120 at a first end 12 of the substrate 10 and a second portion, such as a second track 114, configured to drive or support the substrate carrier 120 at a second end 14 of the substrate 10 opposite the first end 12 of the substrate 10. The second transport assemb1y130 includes a further first portion, such as a further first track 132, configured to support the mask carrier 140 at a first end 22 of the mask 20 and a further second portion, such as a further second track 134, configured to support the mask carrier 140 at a second end 24 of the mask 20 opposite the first end 22 of the mask20. A first distance D between the first portion and the second portion of the first transport assemblyl10 and a second distance D′ between the further first portion and the further second portion of the second transport assemb1y 130 can for some embodiments be essentially equal or essentially the same. The distance(s) can be defined in a second direction (the y-direction), which can be an essentially vertical direction.

Embodiments described herein refer to an alignment between a substrate carrier and a mask carrier with an alignment system. The alignment system is mounted to the vacuum chamber with a mechanical isolation element such as a vibration damper or oscillation damper. Further, an actuator of the alignment system, which is connected to the substrate carrier and the mask carrier is connected to the vacuum chamber via the mechanical isolation element, particularly only via the mechanical isolation element. That is, the mechanical connection path between the substrate carrier and the mask carrier is a direct path, i.e. not via the vacuum chamber or a wall of the vacuum chamber.

Such an alignment system may be particularly beneficial for track assemblies having essentially the same distances, namely the first distance D and the second distance D′. The first transport assemblyl10 or track assembly can be sized to be able to also transport the mask carrier 140, and the second transport assembly 130 or track assembly can be sized to be able to also transport the substrate carrier 120. The first transport assembly 110 and the second transport assembly 130 can be flexibly used while providing an accurate and smooth transportation of the carriers through the vacuum system.

As used throughout the present disclosure, “essentially equal” or “essentially the same” is understood particularly when referring to distances, such as the distances D and D′ between the first and second portions, to allow for a slight deviation from an exact sameness/identity. As an example, the second distance D′ can be in a range of D ± (5%×D), or can be in a range of D ± (1%×D). The deviation can be due to manufacturing tolerances and/or thermal expansion. Yet, the distances are considered essentially equal or essentially the same.

The vacuum chamber can include a chamber wall 201. As exemplarily shown in FIG. 2, the first transport assembly 110 and the second transport assembly 130 can be arranged between the chamber wall 201 of the vacuum chamber and one or more deposition sources 225. In particular, the first transport assembly 110 can be arranged between the chamber wall 201 and the second transport assembly 130. Likewise, the second transport assembly 130 can be arranged between the first transport assembly 110 and the one or more deposition sources 225.

Referring to FIG. 1A, the substrate carrier 120 can include a support structure or body providing a support surface 122, which can be an essentially flat surface configured for contacting e.g. a back surface of the substrate 10. In particular, the substrate 10 can have a front surface (also referred to as “processing surface”) opposite the back surface and on which a layer is deposited during the vacuum processing, such as a vacuum deposition process. The first end 12 of the substrate 10 can be a first edge of the substrate 10, and the second end 14 of the substrate 10 can be a second edge of the substrate 10. The processing surface can extend between the first end or first edge and the second end or second edge.

The first end (or first edge) and the second end (or second edge) can extend essentially parallel to each other, e.g., in the first direction. Likewise, the first end 22 of the mask 20 can be a first edge of the mask 20, and the second end 24 of the mask 20 can be a second edge of the mask. The first end (or first edge) and the second end (or second edge) can extend essentially parallel to each other, e.g., in the first direction, which can be the x-direction.

According to some embodiments, which can be combined with other embodiments described herein, the substrate carrier 120 can be an electrostatic chuck (E-chuck) providing an electrostatic force for holding the substrate 10 and optionally the mask at the substrate carrier 120, and particularly at the support surface 122. As an example, the substrate carrier 120 includes an electrode arrangement (not shown) configured to provide an attracting force acting on at least one of the substrate 10 and the mask 20.

According to some embodiments, the substrate carrier 120 includes the electrode arrangement having a plurality of electrodes configured to provide an attracting force for holding at least one of the substrate 10 and the mask 20 at the support surface 122, and a controller. The controller can be configured to apply one or more voltages to the electrode arrangement to provide the attracting force (also referred to as “chucking force”).

The plurality of electrodes of the electrode arrangement can be embedded in the body, or can be provided, e.g., placed, on the body. According to some embodiments, which can be combined with other embodiments described herein, the body is a dielectric body, such as a dielectric plate. The dielectric body can be fabricated from a dielectric material, preferably a high thermal conductivity dielectric material such as pyrolytic boron nitride, aluminum nitride, silicon nitride, alumina or an equivalent material, but may be made from such materials as polyimide. In some embodiments, the plurality of electrodes, such as a grid of fine metal strips, can be placed on the dielectric plate and covered with a thin dielectric layer.

According to some embodiments, which can be combined with other embodiments described herein, the substrate carrier 120 includes one or more voltage sources configured to apply one or more voltages to the plurality of electrodes. In some implementations, the one or more voltage sources are configured to ground at least some electrodes of the plurality of electrodes. As an example, the one or more voltage sources can be configured to apply a first voltage having a first polarity, a second voltage having a second polarity, and/or ground to the plurality of electrodes.

In the present disclosure, a “mask carrier” is to be understood as a carrier which is configured for holding a mask. For instance, the mask may be an edge exclusion mask or a shadow mask. An edge exclusion mask is a mask which is configured for masking one or more edge regions of the substrate, such that no material is deposited on the one or more edge regions during the coating of the substrate. A shadow mask is mask for configured for masking a plurality of features which are to be deposited on the substrate. For instance, the shadow mask can include a plurality of small openings, e.g. a grid of small openings.

According to some embodiments, which can be combined with other embodiments described herein, the first transport assembly 110 or track assembly and the second transport assembly 130 or track assembly extend in the first direction (x-direction), which can be an essentially horizontal direction. In particular, the first portion, the second portion, the further first portion and the further second portion can all extend in the first direction. In other words, the first portion, the second portion, the further first portion and the further second portion can extend essentially parallel to each other. The extension of the first portion, the second portion, the further first portion and the further second portion can also be referred to as “longitudinal extension”.

In some implementations, the first transport assembly 110 is configured for transportation of the substrate carrier 120 at least in the first direction Likewise, the second transport assembly 130 can be configured for transportation of the mask carrier 140 at least in the first direction. The first direction can also be referred to as “transport direction”.

According to some embodiments, the first portion, such as the first track 112, and the further first portion, such as the further first track 132, are arranged in a first plane defined by the first direction and another direction perpendicular to the first direction. Likewise, the second portion, such as the second track 114, and the further second portion, such as to further second track 134, can be arranged in a second plane defined by the first direction and the other direction. The first plane and the second plane can be essentially parallel to each other. In some implementations, the first plane and the second plane can be essentially vertical planes or essentially horizontal planes.

According to some embodiments, which can be combined with other embodiments described herein, the first direction can be a horizontal direction (x direction). The other direction can be another horizontal direction or a vertical direction. As an example, the other direction can be the second direction (y direction), which can be an essentially vertical direction, or can be the third direction (z direction), which can be an essentially horizontal direction.

In some embodiments, the first distance D and the second distance D′ are defined in a direction perpendicular to the first direction and the other direction, such as the second direction (y direction). The first distance D can be a spacing between the first portion and the second portion, e.g., a spacing between outermost surfaces or edge surfaces of the first portion and the second portion facing each other. Likewise, the second distance D′ can be a spacing between the further first portion and the further second portion, e.g., a spacing between outermost surfaces or edge surfaces of the further first portion and the further second portion facing each other.

According to some embodiments, a third distance or third spacing between the first portion, such as the first track 112, and the other first portion, such as the other first track 132, can be 100 mm or less, specifically 70 mm or less, specifically 50 mm or less, and more specifically 40 mm or less Likewise, a fourth distance or fourth spacing between the second portion, such as the second track 114 and the other second portion, such as the other second track 134, can be 200 mm or less, 100 mm or less, specifically 70 mm or less, and more specifically 50 mm or less. The third distance and the fourth distance can be essentially the same. In some implementations, the third distance and the fourth distance can be defined in the second direction (y direction), which can be a vertical direction, or can be defined in the third direction (z direction), which can be a horizontal direction. The latter case is illustrated in FIG. 2. The distances or spacings can be defined between edges or surfaces of the respective portions facing each other.

According to some embodiments, which can be combined with other embodiments described herein, the apparatus 200 can be configured for contactless levitation and/or contactless transportation of the substrate carrier 120 and/or the mask carrier 140. As an example, the apparatus 200 can include a guiding structure configured for contactless levitation of the substrate carrier 120 and/or the mask carrier 140. Likewise, the apparatus 200 can include a drive structure configured for contactless transportation of the substrate carrier 120 and/or the mask carrier 140. The second track 114 and the further second track can be provide a support arrangements for levitation of a carrier and the first track and further first track can be provided as drive structure for a drive force for transportation, e.g. along the x-direction. In particular, the carrier can be held in a levitating or floating state using magnetic forces instead of mechanical forces. For example, in some implementations, there can be no mechanical contact between the carrier and the transportation track, particularly during levitation, movement and positioning of the substrate carrier and/or mask carrier.

The contactless levitation and/or transportation of the carrier(s) is beneficial in that no particles are generated during transportation, for example due to mechanical contact with guide rails. An improved purity and uniformity of the layers deposited on the substrate 10 can be provided, since particle generation is minimized when using the contactless levitation and/or transportation.

In some implementations, the substrate carrier 120 has a first dimension H (or first extension) and the mask carrier 140 has a further first dimension H′ (or further first extension). The first dimension H and the further first dimension H′ can be defined in a direction perpendicular to the first direction. The first dimension H and the further first dimension H′ can be essentially the same.

According to some embodiments, the first dimension H and the further first dimension H′ are equal to or less than the first distance D and the second distance D′. In other words, the substrate carrier 120 and the mask carrier 140 are smaller than the gap between the first portions and the second portions.

The first gap G1, the second gap G2, the further first gap G1′ and the further second gap G2′ can be essentially the same or equal. A dimension or width of the gap(s) can be defined in a direction perpendicular to the first direction, such as the second direction. As an example, the first gap G1, the second gap G2, the further first gap G1′ and the further second gap G2′ can be less than 30 mm, specifically less than 10 mm, and more specifically less than 5 mm. As an example, at least one of the first gap G1, the second gap G2, the further first gap G1′ and the further second gap G2′ can be in the range between 1 and 5 mm, and preferably in the range between 1 and 3 mm.

One or more deposition sources 225 can be provided in the vacuum chamber. The substrate carrier 120 can be configured to hold the substrate 10 during a vacuum deposition process. The vacuum system can be configured for evaporation of e.g. an organic material for the manufacture of OLED devices. As an example, the one or more deposition sources 225 can be evaporation sources, particularly evaporation sources for depositing one or more organic materials on a substrate to form a layer of an OLED device. The substrate carrier 120 for supporting the substrate 10 can be transported into and through the vacuum chamber, and in particular into and/or through a deposition area, along a transportation path, such as a linear transportation path, provided by the first transport assembly 110.

The material can be emitted from the one or more deposition sources 225 in an emission direction towards the deposition area in which the substrate 10 to be coated is located. For instance, the one or more deposition sources 225 may provide a line source with a plurality of openings and/or nozzles which are arranged in at least one line along the length of the one or more deposition sources 225. The material can be ejected through the plurality of openings and/or nozzles.

The apparatus of the present disclosure can be configured for positioning of a carrier, particularly a substrate carrier and/or a mask carrier. In particular, the apparatus can be configured for moving a substrate carrier and/or a mask carrier along a transport assembly. More specifically, the apparatus can be configured for positioning the substrate carrier in a first position by moving the substrate carrier along the first transport assembly. Additionally, the apparatus can be configured for positioning the mask carrier in a second position by moving the mask carrier along the second transport assembly. For instance, the first transport assembly or track assembly and the second transport assembly or track assembly can be configured for contactless transportation. Accordingly, the apparatus can be configured for moving the substrate carrier and the mask carrier independently from each other, such that the substrate carrier and the mask carrier can be positioned relatively to each other, e.g. for aligning the substrate carrier with the mask carrier.

According to some embodiments, which can be combined with other embodiments described herein, the carriers are configured for holding or supporting the substrate and the mask in a substantially vertical orientation. As used throughout the present disclosure, “substantially vertical” is understood particularly when referring to the substrate orientation, to allow for a deviation from the vertical direction or orientation of ±20° or below, e.g. of ±10° or below. This deviation can be provided for example because a substrate support with some deviation from the vertical orientation might result in a more stable substrate position. Further, fewer particles reach the substrate surface when the substrate is tilted forward. Yet, the substrate orientation, e.g., during the vacuum deposition process, is considered substantially vertical, which is considered different from the horizontal substrate orientation, which may be considered as horizontal ±20° or below.

The term “vertical direction” or “vertical orientation” is understood to distinguish over “horizontal direction” or “horizontal orientation”. That is, the “vertical direction” or “vertical orientation” relates to a substantially vertical orientation e.g. of the carriers, wherein a deviation of a few degrees, e.g. up to 10° or even up to 15°, from an exact vertical direction or vertical orientation is still considered as a “substantially vertical direction” or a “substantially vertical orientation”. The vertical direction can be substantially parallel to the force of gravity.

The embodiments described herein can be utilized for evaporation on large area substrates, e.g., for OLED display manufacturing. Specifically, the substrates for which the structures and methods according to embodiments described herein are provided, are large area substrates. For instance, a large area substrate or carrier can be GEN 4.5, which corresponds to a surface area of about 0.67 m² (0.73×0.92 m), GEN 5, which corresponds to a surface area of about 1.4 m² (1.1 m×1.3 m), GEN 7.5, which corresponds to a surface area of about 4.29 m² (1.95 m×2.2 m), GEN 8.5, which corresponds to a surface area of about 5.7 m² (2.2 m×2.5 m), or even GEN 10, which corresponds to a surface area of about 8.7 m² (2.85 m×3.05 m). Even larger generations such as GEN 11 and GEN 12 and corresponding surface areas can similarly be implemented. Half sizes of the GEN generations may also be provided in OLED display manufacturing.

According to some embodiments, which can be combined with other embodiments described herein, the substrate thickness can be from 0.1 to 1.8 mm. The substrate thickness can be about 0.9 mm or below, such as 0.5 mm. The term “substrate” as used herein may particularly embrace substantially inflexible substrates, e.g., a wafer, slices of transparent crystal such as sapphire or the like, or a glass plate. However, the present disclosure is not limited thereto and the term “substrate” may also embrace flexible substrates such as a web or a foil. The term “substantially inflexible” is understood to distinguish over “flexible”. Specifically, a substantially inflexible substrate can have a certain degree of flexibility, e.g. a glass plate having a thickness of 0.9 mm or below, such as 0.5 mm or below, wherein the flexibility of the substantially inflexible substrate is small in comparison to the flexible substrates.

According to embodiments described herein, the substrate may be made of any material suitable for material deposition. For instance, the substrate may be made of a material selected from the group consisting of glass (for instance soda-lime glass, borosilicate glass, and the like), metal, polymer, ceramic, compound materials, carbon fiber materials or any other material or combination of materials which can be coated by a deposition process.

The term “masking” may include reducing and/or hindering a deposition of material on one or more regions of the substrate 10. The masking may be useful, for instance, in order to define the area to be coated. In some applications, only parts of the substrate 10 are coated and the parts not to be coated are covered by the mask.

FIG. 3A shows a schematic view of an apparatus 300 for vacuum processing according to further embodiments described herein.

The apparatus 300 includes the holding arrangement, e.g. an alignment system 310. The alignment system 310 can be configured to position the substrate carrier 120 and the mask carrier 140 with respect to each other. As an example, the alignment system 310 can be configured to align the substrate carrier 120 and the mask carrier 140 with respect to each other by moving the substrate carrier 120 while keeping the mask carrier 140 stationary, or by moving the mask carrier 140 while keeping the substrate carrier 120 stationary. In yet further examples, both the substrate carrier 120 and the mask carrier 140 can be moved to position or align the substrate carrier 120 and the mask carrier 140 with respect to each other.

According to some embodiments, which can be combined with other embodiments described herein, the holding arrangement, such as an alignment system 310, can be configured for holding the substrate carrier 120 and/or the mask carrier 140. The alignment system 310 can be at least partially arranged between the first transport assembly and the second transport assembly. As an example, one or more holding devices, such as a first mount 316 and a second mount 314, of the alignment system 310 can be arranged between the first portion, such as the first track 112, and the further first portion, such as the further first track 132. One or more further holding devices of an alignment system 310 can be arranged between the second portion, such as the second track 114, and the further second portion, such as the further second track 134. By providing the alignment system 310 at least partially between the first transport assembly and the second transport assembly, an improved alignment of the substrate carrier 120 and the mask carrier 140 can be provided.

In some implementations, the alignment system 310 includes the one or more holding devices, such as first mount 316 and second mount 314, configured to be movable in moving direction parallel to the transport direction (x-direction) and/or a moving direction being different than a substrate transport direction (i.e., the first direction). An actuator 318, indicated by arrows in FIG. 3A can move the first mount 316 and the second mount relative to each other. For instance, the one or more holding devices can be configured to be movable in a direction substantially parallel and/or in a direction substantially perpendicular to a plane of the substrate surface.

A holding arrangement for supporting a substrate carrier and a mask carrier or an alignment system for supporting and aligning the carriers, respectively, is provided. The alignment system can include two or more actuators connectable to at least one of the substrate carrier and the mask carrier. For example, FIG. 3A shows an upper actuator 318 and a lower actuator 318. An actuator can be provided adjacent to all four corners of a rectangular carrier. The alignment system is configured to support the substrate carrier in, or parallel to, a first plane. A first actuator of the two or more actuators can be configured to move the substrate carrier and the mask carrier relative to each other at least in a first direction. A second actuator of the two or more actuators can be configured to move the substrate carrier and the mask carrier relative to each other at least in the first direction and a second direction different from the first direction, and wherein the first direction and the second direction are in the first plane. Yet further, at least one actuator of the two or more alignment actuators can be configured to move the substrate carrier 120 and the mask carrier 140 relative to each other in a third direction (z-direction in FIG. 3A), in particular wherein the third direction is substantially perpendicular to the first plane and/or a substrate surface 11. In some embodiments, at least one actuator of the, for example, four actuators is not configured to actively move a carrier in the first or second direction but only in the third direction.

According to some embodiments, which can be combined with other embodiments described herein, a first actuator can be floating with respect to a second direction, e.g. the y-direction in FIG: 3A. The term “floating” may be understood as the actuator allowing a movement of a carrier in the second direction, e.g., driven by another actuator. As an example, a first actuator is configured to actively move the substrate carrier 120 in the first direction, and is configured to passively allow a movement of the substrate carrier 120 in a second direction. In some implementations, the term “floating” may be understood as “freely moveable”.

In some implementations, the mask carrier 140 can be transported on the second transport assembly to a predetermined position at which the alignment system 310 is provided. The actuators can move the mask carrier 140 in a predetermined position. Thereafter, the substrate carrier 120 can be transported on the first transport assembly to a predetermined position corresponding to the mask carrier 140. The actuators, which are connected to the carriers by a respective first mount and second mount, align the mask carrier and the substrate carrier relative to each other. After alignment the mask can be fixed to the substrate, e.g. by chucking, e.g., with a magnetic or electromagnetic force.

According to some embodiments, which can be combined with other embodiments described herein, the holding arrangement can be or can include an alignment system configured for aligning the substrate carrier 120 relative to the mask carrier 140. In particular, the alignment system can be configured to adjust the position of the substrate carrier 120 with respect to the mask carrier 140. For example, the alignment system can include two or more actuators, for example four actuators. For instance, the alignment system can be configured for aligning the substrate carrier 120 holding the substrate 10 relative to the mask carrier 140 holding the mask 20 in order to provide for a proper alignment between the substrate 10 and the mask 20 during material deposition, e.g. of the organic material.

In some implementations, the mask carrier 140 may be moved into a predetermined mask position on the second transport assembly. Thereafter, the holding arrangement or alignment system 310 may engage to hold the mask carrier 140. After the mask carrier 140 is positioned, the substrate carrier 120 may be moved into a predetermined substrate position. Thereafter, the holding arrangement or alignment system 310 may engage to hold the substrate carrier 120. Then the substrate carrier 120 can be aligned, e.g. by an alignment system as described herein, with respect to the mask carrier 140.

In some implementations, the alignment system includes one or more actuators for positioning the substrate carrier 120 and the mask carrier 40 with respect to each other. As an example, the two or more actuators can be piezoelectric actuators for positioning the substrate carrier 120 and the mask carrier 140 with respect to each other. However, the present disclosure is not limited to piezoelectric actuators. As an example, the two or more alignment actuators can be electric or pneumatic actuators. The two or more alignment actuators can for example be linear alignment actuators. In some implementations, the two or more alignment actuators can include at least one actuator selected from the group consisting of: a stepper actuator, a brushless actuator, a DC (direct current) actuator, a voice coil actuator, a piezoelectric actuator, pneumatic actuators, and any combination thereof.

According to some embodiments, the one or more actuators can be provided between the first transport arrangement and the second transport arrangement. In particular, the one or more alignment actuators can be provided between the substrate carrier 120 and the mask carrier 140. The one or more alignment actuators can be implemented in a space-saving manner, reducing a footprint of the apparatus. Further, the mechanical connection path between a first mount via an actuator to a second mount can be short, e.g. can be at most 300% of the distance between the mask carrier and substrate carrier in the respective predetermined positions, particularly at most 150% of the distance.

According to some embodiments of the present disclosure, the alignment system 310 may be configured for holding the mask carrier and/or the substrate carrier. According to some embodiments which can be combined with other embodiments described herein, the alignment system can include at least two units each having a first mount, a second mount, and an actuator between the first mount and the second mount. A mount can have a reception which can be configured for being connected to at least one mating connecting element provided on the mask carrier or the substrate carrier. For instance, the at least one mating connecting element may be configured as a locking bolt. When the mask carrier and/or the substrate carrier is in a predetermined position, the alignment system and the locking bolts can beneficially be employed for holding the correct position. According to some embodiments, the alignment system may also include mounts, wherein the mounts are connected to a mask carrier and/or a substrate carrier with magnetic forces, e.g. with a magnetic fixing device. The magnetic fixing device can be an electromagnet, which can, for example, be switched on or off. The elctromagnet can be provided by a coil and, for example, a magnetic core. Further, the magnetic fixing device can be an electropermanent magnet, which can, for example be activated or deactivated, i.e. switched on or switched off. Electropermanent magnets may work based on the double magnet principle. One or more first permanent magnets may consist of a “soft” or “semi-hard” magnetic material, i.e. a material with a low coercivity. One or more second permanent magnets may consist of a “hard” magnetic material, i.e. a material with a higher coercivity. Additionally., or alternatively, one or more first permanent magnets may consist of a “soft” or “semi-hard” magnetic material, i.e. a material with a low coercivity, which may be activated with an electromagnet. For example, the one or more mounts may include an electromagnet, which can be switched on for engaging the amount to a mask carrier or a substrate carrier. According to some embodiments, which can be combined with other embodiments described herein, a holding arrangement can include two mounts, i.e. one mount for holding a mask carrier and one mount for holding a substrate carrier. For example two magnetic mounts can be provided for a holding arrangement.

As shown in FIG. 3A, an alignment system 310 can include a mechanical isolation element 312. The mechanical isolation element is provided between the actuator and the position, at which the alignment system is mounted to the vacuum chamber, for example a wall of the vacuum chamber. Accordingly, vibrations, oscillations, or deformations of the vacuum chamber have a reduced influence or no influence on the alignment of mask carrier and the substrate carrier. The mechanical isolation element can be configured to compensate for static and/or dynamic deformations. According to some embodiments, the actuator 318 is provided between a first mount 316 and the second mount 314. The mechanical isolation element 312 is provided between the actuator 318 and the connection of the alignment system to the vacuum chamber, for example to a wall of the vacuum chamber, such as the top wall of the vacuum chamber. The mechanical isolation element is also provided between the mounts and the connection of the alignment system to the vacuum chamber. The direct mechanical connection path between the first mount and the second mount includes the actuator. The direct mechanical connection pass between the first mount and the second mount does not include the mechanical isolation element or a portion of the vacuum chamber, such as a portion of a wall of the vacuum chamber. This arrangement allows for a mechanical decoupling of the actuator and the mounts connected to the actuator from the vacuum chamber.

FIG. 3B shows a schematic view of an apparatus 300 for vacuum processing according to further embodiments described herein. The apparatus 300 includes the alignment system 310. The alignment system 310 can be configured to position the substrate carrier 120 and the mask carrier 140 with respect to each other as described above, e.g. with respect to FIG. 3A.

According to some embodiments, which can be combined with other embodiments described herein, the alignment system 310 can be configured for holding the substrate carrier 120 and/or the mask carrier 140. The alignment system 310 can be at least partially arranged between the first transport assembly and the second transport assembly. As an example, one or more mounts of a holding arrangement can be arranged between the first portion, such as the first track 112, and the further first portion, such as the further first track 132. One or more further mounts of a holding arrangement can be arranged between the second portion, such as the second track 114, and the further second portion, such as the further second track 134. The mounts can, for example, be magnetic elements or a locking bolt.

In some implementations, an alignment system 310 can be arranged at a top wall and/or a bottom wall of the vacuum chamber. The alignment system is provided at least partially within the gap between the mask carrier and the substrate carrier or respective track portions. As an example, an alignment system 310 can extend from the bottom wall to a position between the first portion, such as the first track 112, and the further first portion, such as the further first track 132. Likewise, an alignment system 310 can extend from the top wall to a position between the second portion, such as the second track 114, and the further second portion, such as the further second track 134. According to some embodiments of the present disclosure, which can be combined with other embodiments described herein, an alignment system provided in the gap between the first track and the second track, e.g. a mask track and a carrier track can be provided for an apparatus 300, wherein a mask carrier is larger than a substrate carrier or vice versa. Having the mask carrier larger than the substrate carrier reduces the risk of chamber components, e.g. a portion of a chamber wall be coated with material. For example, there may be an offset between first track 112 and the further first track. Additionally or alternatively, there may be an offset between the second track 114 and the further second track 134.

By providing the alignment system 310 between the first transport assembly and the second transport assembly, an improved alignment of the substrate carrier 120 and the mask carrier 140 can be provided. For example, the length (dimension) of the alignment system, i.e. the distance between a first mount and a second mount connected to an actuator, may be reduced such that inaccuracies may not be increased by a leverage of the length of the arm having the mount. According to one embodiment, an alignment system can be provided at least partially in a gap between the first track and the second track. The alignment system is configured to hold a first carrier, e.g. a substrate carrier, at a side facing the gap and is configured to hold a second carrier, e.g. a mask carrier, at a side facing the gap.

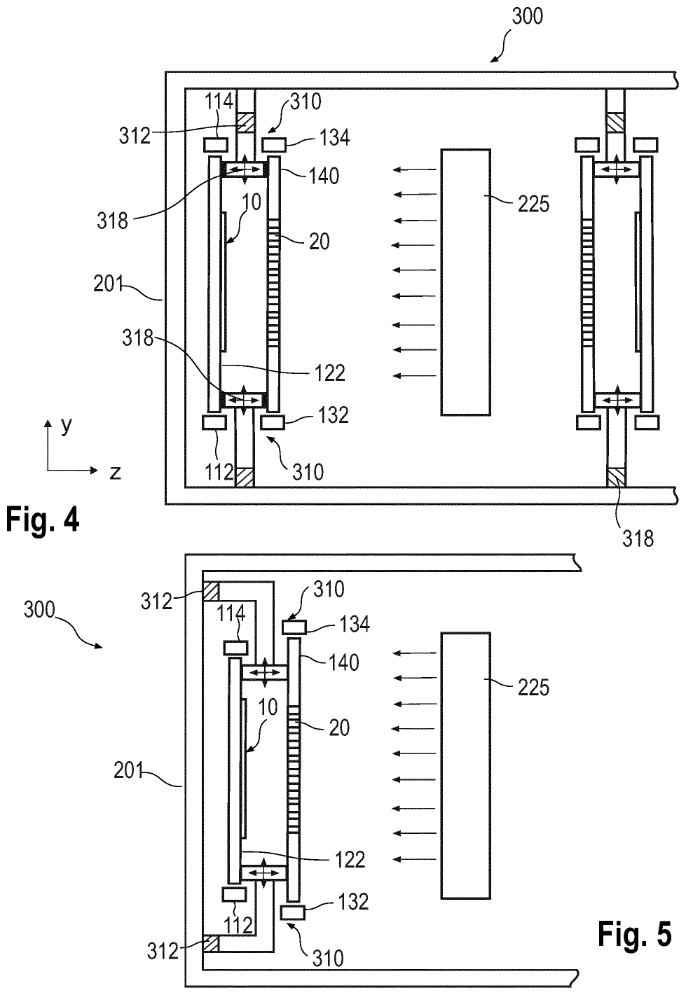

FIG. 4 shows an apparatus 300 for vacuum processing of, for example, material deposition on one or more substrates. A deposition source 225, particularly an evaporation source, can be provided in the vacuum processing chamber. FIG. 4 shows a portion of the vacuum processing chamber, i.e. a sidewall, a top wall and a bottom wall. A substrate 10 in a substrate carrier is provided on both sides of the deposition source. The deposition source can change the direction of evaporation. For example, the deposition source can evaporate to the left-hand side as shown by the arrows in FIG. 4 and may thereafter evaporate to the right-hand side, for example by a rotation of the deposition source 225.

In some implementations, the alignment system 310 can be arranged at a top wall and/or a bottom wall of the vacuum chamber. An example, the alignment system 310 can extend from the bottom wall to a position between the first portion, such as the first track 112, and the further first portion, such as the further first track 132. Likewise, the alignment system 310 can extend from the top wall to a position between the second portion, such as the second track 114, and the further second portion, such as the further second track 134. Between the connection of the alignment system 310 with the top wall and the actuator 318, a mechanical isolation element 312 is provided. The mechanical isolation element 312 mechanically decouples the actuator 318 from the top wall of the vacuum chamber. Between the connection of the other alignment system 310 with the bottom wall and the other actuator 318, a mechanical isolation element 312 is provided. The mechanical isolation element 312 mechanically decouples the other actuator 318 from the bottom wall of the vacuum chamber.

FIG. 5 shows an apparatus for vacuum processing of one or more substrates similar to FIG. 4. Contrary to FIG. 4 the alignment systems shown in FIG. 5 are connected to a sidewall 201 of the vacuum chamber. According to some embodiments, which can be combined with other embodiments described herein, one or more alignment systems can be connected to a sidewall of the vacuum chamber. Additionally or alternatively, one or more alignment system can be connected to a top wall or a bottom wall of the vacuum chamber. In FIG. 5, the alignment systems are connected to the vacuum chamber with a mechanical isolation element 312. According to embodiments described herein, alignment systems are connected with or via mechanical isolation element.

According to some embodiments, which can be combined with other embodiments described herein, the mechanical isolation element can be at least one of a vibration damper, an oscillation damper, a bushing, a rubber bushing, and an active mechanical compensation element. An active mechanical compensation element can be a piezo electronic unit, which actively compensates vibrations or deformations of the vacuum chamber or all of the vacuum chamber. For example, the vacuum chamber may be deformed during evacuation of the system or vibrations from system components, e.g. vacuum pumps, or the building, in which the apparatus is provided, may occur. The mechanical isolation element may compensate for static and dynamic deformations, particularly dynamic deformations. For example, a passive mechanical isolation may be provided by a material/device combination providing a defined mechanical transmission behavior using, e.g. elastomers, a negative stiffness device (NSD), a spring/string, hydraulic/pneumatic damper, tuned mass damper or combinations thereof. A passive mechanical isolation may comprise at least one of an elastomer, a NSD, a spring, a string, a hydraulic damper, a pneumatic damper, and a tuned mass damper. Additionally or alternatively, active isolation can be provided by an active mechanical compensation element, e.g. by at least one of a piezo element, electromagnetic actor, an electroactive polymer (EAP), and a linear motor.

FIG. 9A shows a portion of another apparatus 300 for vacuum processing of one or more substrates. The alignment systems 310 are positioned between the carriers, i.e. the mask carrier and the substrate carrier. According to some embodiments, which can be combined with other embodiment described herein, an alignment system 310 can be configured to provide alignment in three directions or axes, such as x-, y-, and z-direction illustrated in FIGS. 9A and 9B. For example, one alignment system may be configured for alignment along one direction and another alignment system may be configured for alignment along another direction. Additionally or alternatively, an alignment system may be configured for alignment along two or more directions. For example, alignment along two or more directions can be provided with one actuator or a combination of actuators.

Holding devices or mounts (314, 316) can provide a connection between the alignment system and the carriers. For example, magnetic clamps can be used. That magnetic clamps can be provided by electromagnets, electro permanent magnets and/or switchable magnets. FIG. 9B shows a side view such that the second mount 314, which are connected to frame 910 are seen. According to some embodiments, which can be combined with other embodiments described herein, the alignment system 310 are mounted to the frame 910. The frame 910 can be mounted to the vacuum chamber, for example the top wall and a bottom wall of the vacuum chamber with connections including the mechanical isolation element 312.

FIG. 9B shows four connections with mechanical isolation element 312 between the frame 910 and walls of the vacuum chamber (not shown). Six alignment systems having mounts and actuators are connected to the frame 910. According to some embodiments, which can be combined with other embodiments described herein, the number of connections including mechanical isolation elements between the vacuum chamber and a frame is equal or less then a number of alignment systems mounted to the frame. Using a frame for mounting of alignment systems to the frame, particularly a stiff frame, allows for direct mechanical connection path between the alignment systems, which improves the overall alignment. Further, as described above, the frame can be mechanically isolated from the vacuum chamber via mechanical isolation elements. Accordingly, embodiments described herein may provide a vibration isolated aligner for decoupled relative alignment of mask and substrate carriers. Embodiments described herein may provide a direct mechanical connection path between the mask carrier and the substrate carrier via the actuator and excluding the vacuum chamber from the direct mechanical connection path. Further, a direct mechanical connection path of a mount to the vacuum chamber is provided via the mechanical isolation element and may be provided additionally via the frame.

According to some embodiments, alignment of a mask carrier and substrate carrier relative to each other can be provided by having those carriers in the respective tracks with a distance to the holding devices, i.e. mounts or clamps of the alignment systems, for example alignment systems mounted to a frame. The mask carrier can be brought into the clamping position by an actuator (along z-direction in FIG. 9A) and can be claimed to the alignment systems. The substrate carrier can be brought into the clamping position by an actuator (along z-direction in FIG. 9A) and can be clamped to the alignment systems. The alignment system, which can be connected to a frame, provide alignment in all three directions between the two carriers. After the alignment, the mask can be chucked to the substrate.

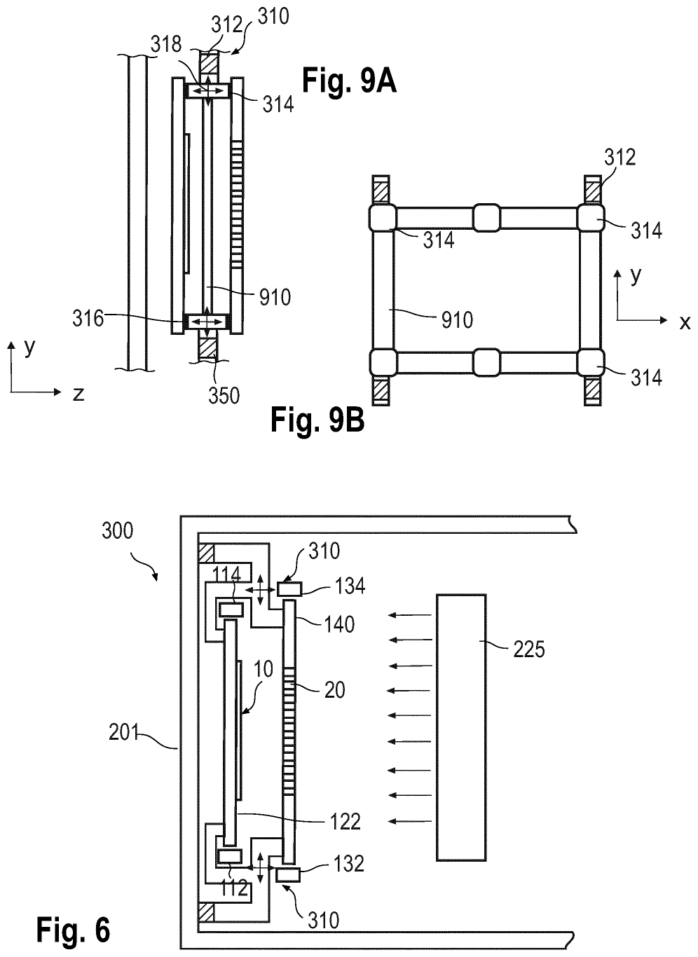

FIG. 6 shows another apparatus 300 for vacuum processing of one or more substrates. The alignment systems 310 shown in FIG. 6 include a first mount provided between the substrate carrier and the mask carrier or in a plane parallel to the gap between the substrate carrier and the mask carrier, i.e. the first transport assembly and the second transport assembly, respectively. A further mount of the alignment system is provided on an opposing side of the substrate carrier or the transport assembly, respectively. Accordingly, the mask carrier and the substrate carrier amounted by the mounts from the same side. Alternatively to the embodiment illustrated in FIG. 6, wherein the mounts contact the carriers from the left-hand side, the mounts may also contact the carriers from the right-hand side. As shown in FIG. 6, at least a portion of the alignment system 310 is provided within the gap or adjacent to the gap. The alignment system 310 is connected to the vacuum chamber with or via a mechanical isolation element. According to yet further embodiments, a similar concept may be possible, wherein the first mount of an alignment system and a second mount of an alignment system connect to a respective carrier from the sides opposing the gap. Such an arrangement may also allow for a mechanical connection path between the mounts and the vacuum chamber we are the mechanical isolation element only.

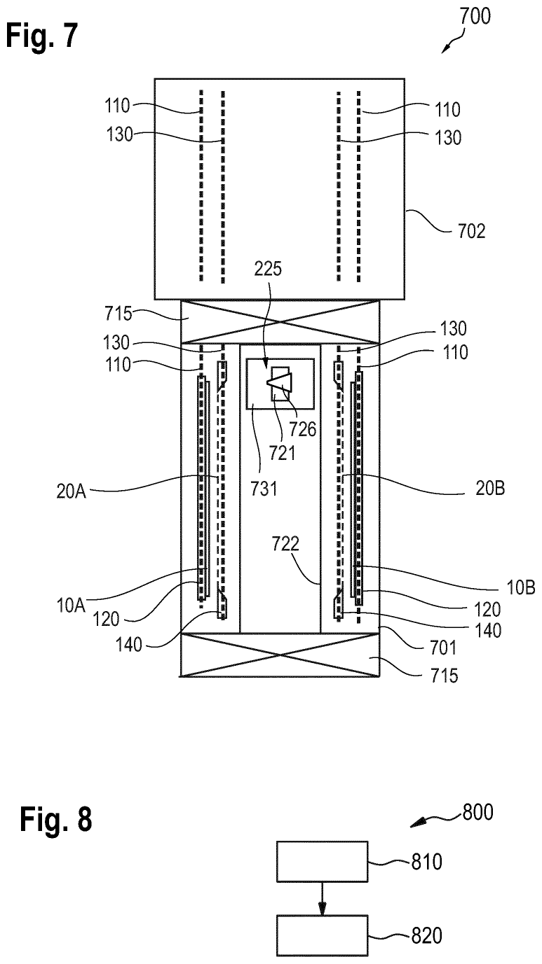

FIG. 7 shows a schematic view of a system 700 for vacuum processing of a substrate according to embodiments described herein.

The system 700 includes the apparatus for vacuum processing of a substrate according to the embodiments described herein, the substrate carrier 120 and the mask carrier 140. In some implementations, the first transport assembly 110 is configured for transportation of the substrate carrier 120 and the mask carrier 140, and/or the second transport assembly 130 is configured for transportation of the substrate carrier 120 and the mask carrier 140.

According to some embodiments, which can be combined with any other embodiments described herein, the system 700 includes the vacuum chamber (e.g. a vacuum processing chamber 701) having an apparatus according to any embodiments described herein. Further, the system 700 includes at least one further chamber 702 having a transport arrangement. The at least one further chamber 702 can be a rotation module, a transit module, or a combination thereof. In the rotation module, the transport assembly and the carrier(s) arranged thereon can be rotated around a rotational axis, such as a vertical rotation axis. As an example, the carrier(s) can be transferred from the left side of the system 700 to the right side of the system 700, or vice versa. The transit module can include tracks such that carrier(s) can be transferred through the transit module in different directions. The vacuum processing chamber 701 can be configured for depositing organic materials. A deposition source 225, particularly an evaporation source, can be provided in the vacuum processing chamber 701. The deposition source 225 can be provided on a track or linear guide 722, as exemplarily shown in FIG. 7. The linear guide 722 may be configured for the translational movement of the deposition source 225. Further, a drive for providing a translational movement of deposition source 725 can be provided. In particular, a transportation apparatus for contactless transportation of the deposition source 225 may be provided.

A source support 731 configured for the translational movement of the deposition source 225 along the linear guide 722 may be provided. The source support 731 can support an evaporation crucible 721 and a distribution assembly 726 provided over the evaporation crucible 721. Accordingly, the vapor generated in the evaporation crucible 721 can move upwardly and out of the one or more outlets of the distribution assembly. Accordingly, the distribution assembly 726 is configured for providing evaporated organic material, particularly a plume of evaporated source material, from the distribution assembly to the substrate.

As exemplarily shown in FIG. 7, the vacuum processing chamber 701 may have gate valves 715 via which the vacuum processing chamber 701 can be connected to an adjacent further chamber 702, e.g. a routing module or an adjacent service module. In particular, the gate valves 715 allow for a vacuum seal to the adjacent further chamber and can be opened and closed for moving a substrate and/or a mask into or out of the vacuum processing chamber 701.

In the present disclosure, a “vacuum processing chamber” is to be understood as a vacuum chamber or a vacuum deposition chamber. The term “vacuum”, as used herein, can be understood in the sense of a technical vacuum having a vacuum pressure of less than, for example, 10 mbar. The pressure in a vacuum chamber as described herein may be between 10⁻⁵ mbar and about 10⁻⁸ mbar, specifically between 10⁻⁵ mbar and 10⁻⁷ mbar, and more specifically between about 10⁻⁶ mbar and about 10⁻⁷ mbar. According to some embodiments, the pressure in the vacuum chamber may be considered to be either the partial pressure of the evaporated material within the vacuum chamber or the total pressure (which may approximately be the same when only the evaporated material is present as a component to be deposited in the vacuum chamber). In some embodiments, the total pressure in the vacuum chamber may range from about 10⁻⁴ mbar to about 10⁻⁷ mbar, especially in the case that a second component besides the evaporated material is present in the vacuum chamber (such as a gas or the like).

With exemplary reference to FIG. 7, according to embodiments which can be combined with any other embodiment described herein, two substrates, e.g. a first substrate 10A and a second substrate 10B, can be supported on respective transportation tracks, such as respective first transport assemblys 110 as described herein. Further, two tracks, e.g. two second transport assemblys 120 as described herein, for providing mask carriers 140 thereon can be provided. In particular, the tracks for transportation of a substrate carrier 120 and/or a mask carrier 140 may be configured as described with reference to FIGS. 1 to 6.

In some embodiments, coating of the substrates may include masking the substrates by respective masks, e.g. by an edge exclusion mask or by a shadow mask. According to some embodiments, the masks, e.g. a first mask 20A corresponding to the first substrate 10A and a second mask 20B corresponding to the second substrate 10B, are provided in a mask carrier 140 to hold the mask in a predetermined position, as exemplarily shown in FIG. 7.

According to some embodiments, which can be combined with other embodiments described herein, the substrate is supported by the substrate carrier 120, which can be connected to an alignment system as described herein (not shown in FIG. 7). The alignment system can be configured for adjusting the position of the substrate with respect to the mask. It is to be understood that the substrate can be moved relative to the mask in order to provide for a proper alignment between the substrate and the mask during deposition of the organic material. According to a further embodiment, which can be combined with other embodiments described herein, alternatively or additionally the mask carrier 140 holding the mask can be connected to the alignment system. Accordingly, either the mask can be positioned relative to the substrate or the mask and the substrate can both be positioned relative to each other. An alignment system as described herein may allow for a proper alignment of the masking during the deposition process, which is beneficial for high quality or OLED display manufacturing.

Examples of an alignment of a mask and a substrate relative to each other include actuators, which can allow for a relative alignment in at least two directions defining a plane, which is essentially parallel to the plane of the substrate and the plane of the mask. For example, an alignment can at least be conducted in an x-direction and a y-direction, i.e. two Cartesian directions defining the above-described parallel plane. Typically, the mask and the substrate can be essentially parallel to each other. Specifically, the alignment can further be conducted in a direction essentially perpendicular to the plane of the substrate and the plane of the mask. Thus, an alignment unit is configured at least for an X-Y-alignment, and specifically for an X-Y-Z-alignment of the mask and the substrate relative to each other. One specific example, which can be combined with other embodiments described herein, is to align the substrate in x-direction, y-direction and z-direction to a mask, which can be held stationary in the vacuum processing chamber.

FIG. 8 shows a flow chart of a method 800 for aligning of a substrate carrier and a mask carrier in a vacuum chamber according to embodiments described herein. The method 800 can utilize the apparatuses and systems according to the present disclosure.

A method may include aligning a substrate carrier and the mask carrier relative to each other with an actuator of the alignment system (see box 810). At least one of mechanical noise, vibrations from the system, and vibrations from the building, i.e. dynamic and static deformations, which may be transferred from the vacuum chamber, for example, from wall of the vacuum chamber, to the actuator is compensated or reduced (see box 810).

Further, a method may include providing a direct mechanical connection path between the mask carrier and the substrate carrier via the actuator. For example, the direct mechanical connection path does not include a portion of the vacuum chamber, for example a portion of the wall of the vacuum chamber. According to some embodiments, which can be combined with other embodiments described herein, transportation of carriers, for example substrate carriers and/or mask carriers on a respective track assembly or transport assembly can be provided with magnetic levitation system for a contactless transportation of the carriers. The carriers can be pre-aligned relative to each other with the contactless transportation systems. After the pre-alignment, the alignment system may connect to the carriers, for example with first mount and a second amount, and can provide for the fine alignment with mechanical contact, e.g. mechanical contact of the alignment system. The mechanical fine alignment can be provided by the actuator according to embodiments described herein.

The combination of a pre-alignment of a contactless transportation system, for example a magnetic levitation system, and a fine alignment with mechanical contact by the actuators allows for an alignment system with reduced complexity and, thus, reduced cost of ownership. This may, for example, be provided by the pre-alignment with the levitation system.

According to embodiments described herein, the method for aligning and/or transportation of a substrate carrier and a mask carrier in a vacuum chamber can be conducted using computer programs, software, computer software products and the interrelated controllers, which can have a CPU, a memory, a user interface, and input and output devices being in communication with the corresponding components of the apparatus.

The present disclosure provides a first transport assembly for a substrate carrier and a second transport assembly for a mask carrier that may be equally sized in at least one dimension. In other words, the mask carrier may fit into the first transport assembly or track assembly and the substrate carrier may fit into the second transport assembly or track assembly. The first transport assembly and the second transport assembly can be flexibly used while providing an accurate and smooth transportation of the carriers through the vacuum system. The alignment system or the holding arrangement, respectively, allows for a precise alignment of the substrate with respect to the mask, or vice versa. A high quality processing results, e.g. for production of high resolution OLED devices, can be achieved.

While the foregoing is directed to embodiments of the disclosure, other and further embodiments of the disclosure may be devised without departing from the basic scope thereof, and the scope thereof is determined by the claims that follow.

1. An apparatus for processing a substrate, comprising:
a vacuum chamber;
a substrate transport assembly in the vacuum chamber;
a mask transport assembly in the vacuum chamber; and
an alignment system comprising an actuator in the vacuum chamber; and
a mechanical isolation element between the actuator and the vacuum chamber.

2. The apparatus according to claim 1, wherein the alignment system is mounted to a frame.

3. The apparatus according to claim 1, wherein the alignment system comprises:
a first mount for mounting a substrate carrier to the alignment system and a second mount for mounting a mask carrier to the alignment system.

4. The apparatus according to claim 3, wherein the actuator is provided in a mechanical connection path between the mechanical isolation element and the first mount and is provided in a mechanical connection path between the mechanical isolation element and the second mount.

5. The apparatus according to claim 3, wherein the actuator is configured to move the first mount and the second mount relative to each other.

6. The apparatus according to claim 3, wherein the actuator is connected to the first mount and to the second mount and is provided between the first mount and the second mount.

7. The apparatus according to claim 3, wherein at least one of the first mount and the second mount comprises a magnetic fixing device.

8. The apparatus of claim 7, wherein the magnetic fixing device comprises at least one of an electromagnet or an electropermanent magnet.

9. The apparatus according to claim 1, wherein the actuator is selected from the group consisting of: a stepper actuator, a brushless actuator, a DC (direct current) actuator, a voice coil actuator, a pneumatic actuator and a piezoelectric actuator.

10. The apparatus according to claim 3, wherein at least a portion of the alignment system is provided between the mask transport assembly and the substrate transport assembly.

11. The apparatus according to claim 10, wherein at least one of the first mount and the second mount are provided between the mask transport assembly and the substrate transport assembly.

12. The apparatus according to claim 10, wherein the first mount and the second mount are mechanically connected via the actuator.

13. The apparatus according to claim 1, wherein the mechanical isolation element is at least one of a vibration damper, an oscillation damper, a bushing, a rubber bushing, and an active mechanical compensation element.

14. A system for processing a substrate, comprising:
an apparatus for processing a substrate, the apparatus comprising:
a vacuum chamber;
a substrate transport assembly in the vacuum chamber;
a mask transport assembly in the vacuum chamber;
an alignment system comprising an actuator in the vacuum chamber;
a mechanical isolation element between the actuator and the vacuum chamber;
a substrate carrier provided on the substrate transport assembly; and
a mask carrier provided on the mask transport assembly.

15. The system of claim 14, wherein the substrate transport assembly is configured for contactless transportation of the substrate carrier and the mask transport assembly is configured for contactless transportation of the mask carrier.

16. A method for aligning a substrate carrier and a mask carrier in a chamber, comprising:
aligning the substrate carrier and the mask carrier relative to each other with an alignment system comprising one or more actuators in the vacuum chamber; and
compensating or reducing at least one of mechanical noise, dynamic deformations and static deformations transferred from the vacuum chamber to the actuator.

17. The method according to claim 16, further comprising:
mounting the mask carrier to the actuator; and
mounting the substrate carrier to the actuator, wherein a direct mechanical connection path between the mask carrier and the substrate carrier is provided via the actuator.

18. The method according to claim 16, further comprising:
contactlessly transporting the substrate carrier on a substrate transport assembly;
contactlessly transporting the substrate carrier on a mask transport assembly; and
aligning the substrate carrier and the mask carrier relative to each other with at least one of the substrate transport assembly and the mask transport assembly.

19. The apparatus according to claim 2, wherein the alignment system comprises:
a first mount for mounting a substrate carrier to the alignment system and a second mount for mounting a mask carrier to the alignment system.

20. The apparatus of claim 11, wherein the first mount and the second mount are mechanically connected via the actuator.
